(19) United States
(12) Patent Application Publication
(10) Pub. No.: US 2010/0205517 A1
(43) Pub. Date: Aug. 12, 2010

(54) Solid State Disk Device and Program Fail Processing Method Thereof

(76) Inventors: Doogie Lee, Yongin-si (KR); Wonchul Ju, Seoul (KR)

Correspondence Address: F. CHAU & ASSOCIATES, LLC, 130 WOODBURY ROAD, WOODBURY, NY, 11797, US

(21) Appl. No.: 12/643,560

(22) Filed: Dec. 21, 2009

(30) Foreign Application Priority Data
Feb. 10, 2009 (KR) 10-2009-0010548

(51) Int. Cl. H03M 13/09; G06F 11/10

(52) U.S. Cl. 714/807; 714/799; 714/E11.032

(57) ABSTRACT

A solid state disk device includes at least one nonvolatile memory and a controller reporting an error code to a host for requesting a previously received data and a command corresponding to the data when a program fail occurs in the nonvolatile memory. The error code is one of a plurality of error codes defined in an interface supported by the controller or a data transmission protocol supported by the nonvolatile memory.

### CROSS-REFERENCE TO RELATED APPLICATIONS

This U.S. non-provisional patent application claims priority under 35 U.S.C. §119 to Korean Patent Application 10-2009-0010548, filed on Feb. 10, 2009, the entire contents of which are hereby incorporated by reference.

### BACKGROUND

The present disclosure herein relates to an electronic device, and more particularly, to a solid state disk device and a program fail processing method of the solid state disk device.

With the advent of information centric societies, the amount of data that individuals store and carry has increased. A variety of individual data storage devices have been developed to cope with the increase.

Among the data storage devices, a hard disk drive (HDD) has been widely used due to a high record density, a high data transmission speed, a fast data access time, low cost, and the like. However, since the hard disk drive has a complicated structure of moving mechanical components, it is susceptible to damage by small impacts and vibrations.

A solid state disk (SSD) using a flash memory has been developed as a data storage device that can replace the hard disk drive. Unlike the hard disk drive, the SSD has no moving mechanical structure. Therefore, the SSD can reduce latency and drive time compared to the hard disk drive and can execute reading/programming operations at a high speed. Since the SSD can reduce errors caused by latency and mechanical friction, it can improve reliability of the reading/programming operations. Moreover, since heat and noise rarely occur during the operation of the SSD and the SSD is largely resistant to external impacts, the SSD is estimated to be suitable for a portable device, compared to the known HDD.

### SUMMARY

According to embodiments of the inventive concept, a solid state disk device includes at least one nonvolatile memory, and a controller reporting an error code to a host for requesting a previously received data and a command corresponding to the data when a program fail occurs in the nonvolatile memory. In this case, the error code is one of a plurality of error codes defined in an interface supported by the controller or a data transmission protocol supported by the nonvolatile memory.

In some embodiments, the error code may be defined in the interface or the data transmission protocol to process errors other than the program fail.

In some embodiments, the solid state disk device may further include a flash translation layer monitoring whether the program fail occurs in the nonvolatile memory and reporting the error code to the host when the program fail occurs.

In some embodiments, the error code may include a CRC (Cyclic Redundancy Checking) error code.

In some embodiments, the data transmission protocol may include an Ultra DMA (Direct Memory Access) protocol.

In some embodiments, the interface may include an ATA (AT Attachment) interface.

In some embodiments, the controller may report the error code to the host whenever the program fail is detected in the nonvolatile memory without storing the previously received data and command to additional memory.

According to embodiments of the inventive concept, a program fail processing method of a solid state disk device includes programming at least one nonvolatile memory in response to program command and data received from a host, reporting an error code to the host for requesting the data and the program command, the data and the program command being previously received, when a program fail occurs in the nonvolatile memory, re-receiving the data and the command corresponding to the reported error code from the host, and re-programming the data re-received from the host to the nonvolatile memory.

In some embodiments, the error code may be one of a plurality of error codes defined in an interface or a data transmission protocol supported by the solid state disk device to process errors other than the program fail.

In some embodiments, the error code may include a CRC (Cyclic Redundancy Checking) error code.

In some embodiments, the data transmission protocol may include an Ultra DMA (Direct Memory Access) protocol.

In some embodiments, the interface may include an ATA (AT Attachment) interface.

In some embodiments, the programming and the re-programming may execute an interleaved program operation that successively programs a plurality of nonvolatile memories electrically connected to a plurality of channels.

In some embodiments, the reporting of the error code may include reporting the error code to the host when the program fail is detected in any one of the plurality of flash memories.

In some embodiments, the reporting of the error code to the host is performed without storing the previously received data and program command to additional memory.

According to embodiments of the inventive concept, a computing system includes a host, and a solid state disk device writing or reading out data by request of the host. In this case, the solid state disk device includes at least one nonvolatile memory, and a controller reporting an error code to the host for requesting a previously received data and a command corresponding to the data when a program fail occurs in the nonvolatile memory, and the error code is one of a plurality of error codes defined in an interface supported by the controller or a data transmission protocol supported by the nonvolatile memory.

In some embodiments, the controller reports the error code to the host whenever the program fail occurs in the nonvolatile memory without storing the previously received data and command to additional memory

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept. In the drawings:

FIG. 1 is a block diagram illustrating a schematic configuration of a solid state disk system according to an embodiment of the inventive concept;

FIG. 2 is a view illustrating more fully a configuration of a controller of FIG. 1;

FIG. 3 is a timing diagram explaining a program fail processing method to which a CRC error code is not applied;

FIG. 4 is a timing diagram explaining a program fail processing method according to an embodiment of the inventive concept to which a CRC error code is applied;

FIG. 5 is a flowchart illustrating the program fail processing method according to an embodiment of the inventive concept; and

FIG. 6 is a view illustrating a computing system according to an embodiment of the inventive concept.

### DETAILED DESCRIPTION OF PREFERRED EMBODIMENTS

Exemplary embodiments of the inventive concept will be described below in more detail with reference to the accompanying drawings. Embodiments of the inventive concept may, however, be embodied in many different forms and should not be construed as being limited to embodiments set forth herein. Rather, embodiments are provided so that this disclosure will be thorough and complete and will fully convey the scope of the inventive concept to those skilled in the art, and embodiments of the inventive concept will only be defined by the appended claims. Like reference numerals refer to like elements throughout the specification.

A solid state disk device according to embodiments of the inventive concept artificially reports a prescribed error code to a host whenever a program fail occurs. The host retransmits a corresponding command and data in which the program fail occurs (program-failed data), to the solid state disk device in response to the error code reported by the solid state disk device. The error code to be transmitted to the host for the purpose of retransmitting the program-failed data may be utilized one of a plurality of error codes defined in a data transmission protocol of a bus or an interface of the solid state disk device, although the error codes were defined originally without considering the program fail of the flash memories. According to a program fail processing method of an embodiment of the inventive concept, a program operation may be re-executed with respect to the program-failed data without defining a specific error code and a specific flow for processing the program fail. Therefore, the solid state disk device may store a previously programmed data or a previously received program data without an additional memory.

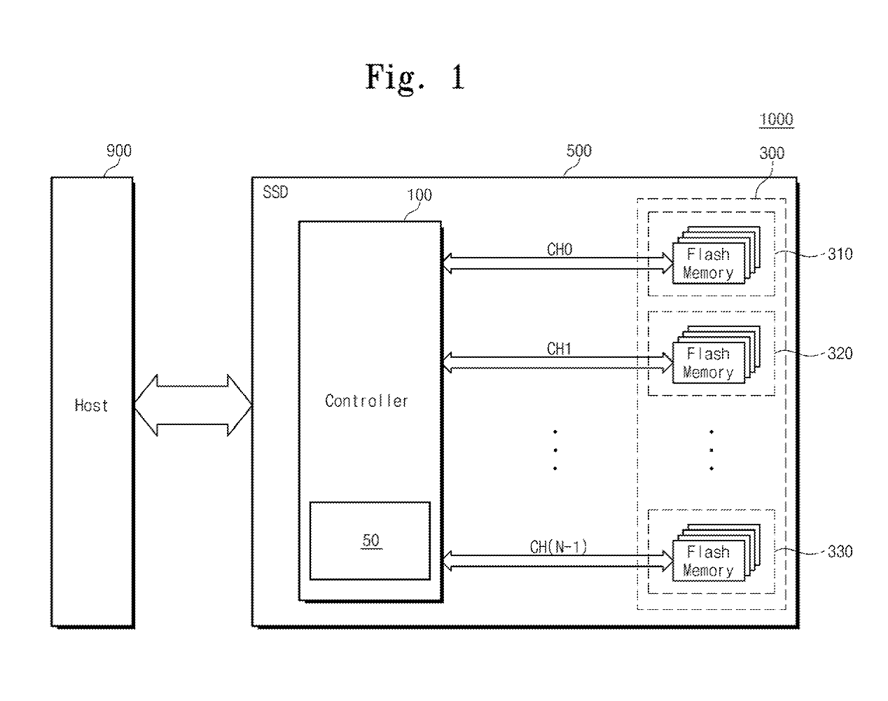

FIG. 1 is a block diagram illustrating a schematic configuration of a solid state disk system 1000 according to an embodiment of the inventive concept.

Referring to FIG. 1, a Solid State Disk (SSD) device 500 may be divided into a controller 100 and a data storage unit 300. The data storage unit 300 is a data storage medium that stores data using, for example, semiconductor chips.

The data storage unit 300 may preferably be provided with nonvolatile memories such as a flash memory. N channels (where N is an integer that is 1 or greater than 1) may be provided between the controller 100 and the data storage unit 300. A plurality of flash memories 310 to 330 may be electrically connected to each of the channels CH0 to CH(N−1). The plurality of flash memories 310 to 330 connected to each of the channels CH0 to CH(N−1) may constitute a plurality of data paths.

The channels CH0 to CH(N−1) may imply an independent bus that transmits the command and data to the corresponding flash memories 310 to 330. The flash memories 310 to 330 may be connected to different channels respectively and may be independently operated. The pages ways may imply the aggregation of flash memories holding one channel in common. Each of the flash memory chips may be discriminated according to the corresponding channel and pageway. A Logical Block Address (LBA) transmitted from a host 900 may determine which flash memory chip of any pageway of any channel executes the command provided from the host 900.

Embodiments of the inventive concept will illustratively describe a case that the data storage unit 300 may be implemented with the flash memories. The nonvolatile memory of the data storage unit 300, however, is not limited to a specific kind and a specific type, but may be configured in various types. For example, the nonvolatile memories 310 to 330 of the data storage unit 300 may include a nonvolatile memory such as MRAM or PRAM as well as a flash memory. In addition, the data storage unit 300 may be constituted by a volatile memory such as a DRAM or a SRAM.

The number of data bits, which is stored in each of the memory cells of the flash memories 310 to 330 constituting the data storage unit 300, may be implemented in various types. For example, the flash memories 310 to 330 may be implemented with single-level flash memory cells storing 1-bit data per cell and multi-level flash memory cells storing multi-bit data per cell. In addition, the flash memories 310 to 330 may be implemented as mixed types of the single-level flash memory cells and the multi-level flash memory cells. The memory cells constituting the flash memories 310 to 330 may be variously implemented. For example, the flash memories 310 to 330 may be implemented with NAND flash memory cells or NOR flash memory cells, and the flash memories 310 to 330 may be implemented as mixed types of the NAND flash memory cells and the NOR flash memory cells. Furthermore, the flash memories 310 to 330 may be One-NAND flash memory in which flash memory core and memory control logic are formed into a single chip.

The flash memories 310 to 330 may be implemented with memory cells having a charge storage layer configured in various types. For example, the charge storage layer may be formed of conductive polycrystalline silicon and be formed using an insulating layer such as Si₃N₄, Al₂O₃, HfAlO, and HfSiO. The flash memory using the insulating layer such as Si₃N₄, Al₂O₃, HfAlO, and HfSiO as a charge storage layer is also referred to as a Charge Trap Flash (CTF) memory.

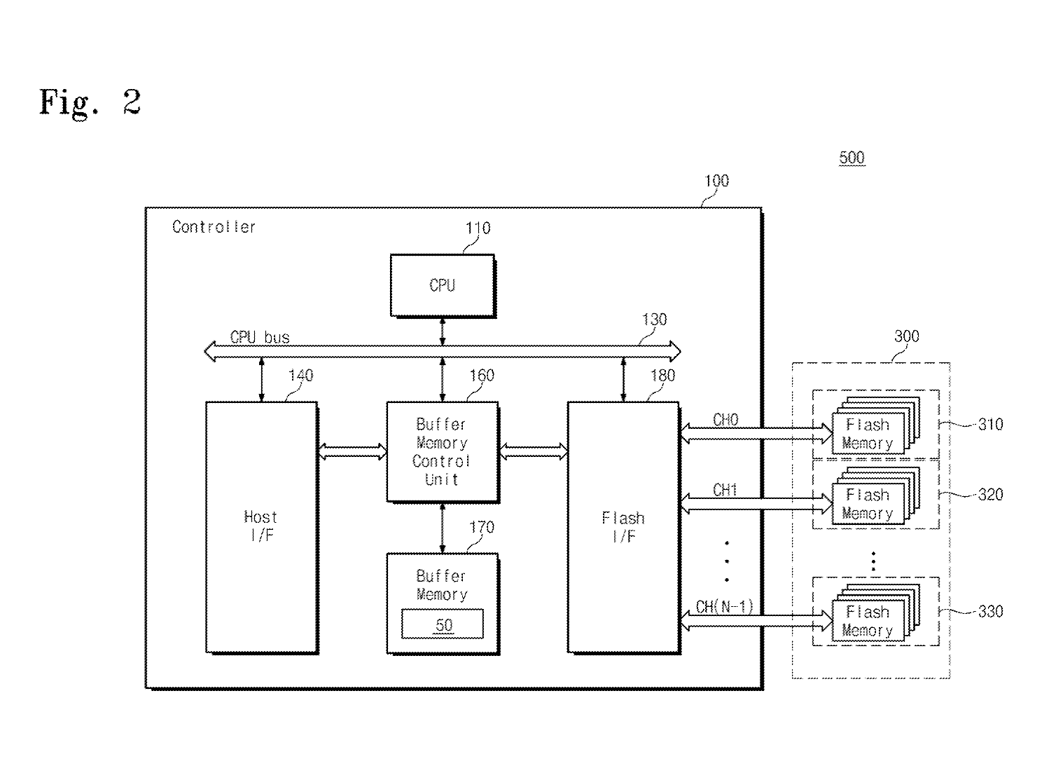

The controller 100 may exchange data with the host 900 through one of various interfaces such as a Universal Serial Bus (USB), MultiMediaCard (MMC), PCIExpress (PCIE), AT Attachment (ATA), Serial AT Attachment (SATA), Parallel AT Attachment (PATA), Small Computer System Interface (SCSI), Serial Attached SCSI (SAS), Enhanced Small Disk Interface (ESDI), Integrated Drive Electronics (IDE), etc. The interface between the controller 100 and the host 900 may be executed in a host interface (see reference numeral 140 of FIG. 2) of the controller 100.

The controller 100 may control a programming, erasing, and reading operation of the data storage unit 300 in response to the command input from the host 900. Specifically, the controller 100 may process a program fail using a Flash Translation Layer (hereinafter, referred to as FTL) 50. In an embodiment of the inventive concept, the FTL 50 may artificially report an error code to the host 900 when the program fail occurs in any one of the plurality of flash memories constituting the data storage unit 300. The host 900 may retransmit the command and data corresponding to the program-failed data to the solid state disk device 500 in response to the error code reported from the FTL 50.

The error code transmitted to the host 900 for the purpose of processing the program fail, may utilize one of a plurality of error codes originally defined in an interface provided between the solid state disk device 500 and the host 900 or a data transmission protocol supported by the bus inside the solid state disk device 500, although the error codes were originally defined without considering the program fail of the flash memories. In an embodiment of the inventive concept, one of error codes originally defined in the interface or the data transmission protocol (for example, CRC error) may substitute for a specific error code for the flash memories to process the program fail. The error code for processing the CRC error is called a CRC error code.

Embodiments of the inventive concept will illustratively describe different cases. For example, an ATA interface may be provided between the solid state disk device 500 and the host 900, and the data storage unit 300 may be provided with the flash memories supporting an ultra DMA protocol. However, the interface and data transmission protocol may be changed and modified without being limited to a specific type.

The program fail processing method according to an embodiment of the inventive concept may substitute the error code (for example, CRC error code) originally defined in the interface or protocol for the specific error code for the flash memories. Accordingly, the program fail processing method according to an embodiment of the inventive concept can be performed without defining a specific error code and a specific flow for processing the program fail. As a result, the program fail processing method may execute a re-program with respect to the program-failed data by following to an error processing flow (for example, a CRC error processing flow) originally defined in the interface or protocol, without a specific internal operation for processing the program fail. Since the re-program may be executed, the solid state disk device 500 does not require an additional memory for storing the previously received program data or previously programmed data. According to an embodiment of the inventive concept, the program fail processing may be applied in cases when data is simultaneously programmed or a plurality of program operations is successively executed, for example, when two-plane page program for simultaneously programming two page data or an N-way interleaved program is executed.

FIG. 2 is a view illustrating an exemplary configuration of the controller 100 illustrated in FIG. 1.

Referring to FIG. 2, the controller 100 may include a Central Processing Unit (CPU) 110, a CPU bus 130, a host interface 140, a buffer memory control unit 160, a buffer memory 170, and a flash interface 180. The CPU 110, the host interface 140, the buffer memory control unit 160, the buffer memory 170, and the flash interface 180 may be connected to one another through the CPU bus 130.

The CPU 110 may control various operations of the solid state disk device 500. The host interface 140 may exchange the command, address, and data with the host 900 according to the control of the CPU 110. The buffer memory 170 may temporarily store data input from the host 900 or to be transmitted to the host 900 through the host interface 140. The temporarily stored data may be transmitted to the flash memories 310 to 330 or the host 900. Embodiments of the inventive concept will illustratively describe the case where the host interface 140 supports the ATA interface. However, besides the ATA interface, various interface techniques may be applicable to the host interface 140. For example, as long as the interface defines the error code for requesting the previously received data and the command corresponding to the data, it may be applicable to both the solid state disk device 500 and the program fail processing method thereof.

The flash memories 310 to 330 constituting the data storage unit 300 are a memory may not be overwritten. Therefore, the erasing operation is performed before a programming operation in the flash memories 310 to 330. In each of the flash memories 310 to 330, a data unit of programming operation is different from a data unit of erasing operation. For example, the data unit of the programming operation is smaller than data unit of the erasing operation. In order to hide the erase-before-write characteristics of the flash memories 310 to 330, FTL 50 may be employed between a file system (not illustrated) and the flash memories 310 to 330. Generally, the file system is stored in the form of software toward the host. The FTL 50 may perform an address mapping function mapping a Logical Block Address (LBA) generated by the file system into a Physical Block Address (PBA) of the flash memories 310 to 330 during the programming operation with respect to the flash memories 310 to 330. Due to the address mapping function of the FTL 50, the host 900 may recognize the solid state disk device 500 provided with the flash memories 310 to 330 as a hard disk drive, and may access the flash memory in the same manner as the hard disk drive. In addition, the FTL 50 may execute a bad block managing function, a data backup managing function due to the power interruption, and a wear-level managing function. Further, the FTL 50 may perform the program fail processing of the flash memories 310 330 in an embodiment of the inventive concept.

For example, the FTL 50 may monitor whether the program fail occurs in the flash memories 310 to 330 during the program operation and may control to re-execute the program operation with respect to the program-failed data. The occurrence or nonoccurrence of the program fail may be reported from a control logic (not illustrated) provided inside of each of the flash memories. With respect to the program fail processing function performed in the FTL 50, it will be described more fully below.

The buffer memory control unit 160 may control an access operation (for example, reading/writing/erasing operation) of the buffer memory 170 in response to the control of the CPU 110. The buffer memory 170 may be embodied as a volatile memory (for example, SRAM or DRAM). The buffer memory 170 may temporarily store the transmitted data between the flash memory and the host 900, and may store software required to execute the function of the FTL 50 and the programs to be operated by the CPU 110. For example, the software needed to execute the function of the FTL 50 may be stored in the flash memories 310 to 330 or the corresponding data storage regions (for example, boot code region) and may be loaded onto the buffer memory 170 during power-up operation. In addition, the buffer memory 170 may store additional information processed by the FTL 50, for example, address mapping information of the flash memory.

The flash interface 180 may exchange data with the plurality of flash memories through the plurality of channels CH0 to CH(N−1). The plurality of flash memories may be electrically connected to the plurality of channels CH0 to CH(N−1), respectively. Embodiments of the inventive concept will illustratively describe the case where Ultra DMA protocol is supported between the flash interface 180 and the data storage unit 300. However, the data transmission protocol may be changed and modified in various types without being limited to the specific type in an embodiment of the inventive concept. For example, in case that the data transmission protocol defines the error code (for example, CRC error code) for requesting the previously received data and the command corresponding to the data, the data transmission protocol may be applicable to the solid state disk device 500 and the program fail processing method thereof.

An Ultra DMA (Direct Memory Access) may support an ATA/IDE interface as a protocol for transmitting data between the data storage unit 300 and the buffer memory 170 (for example, RAM) through the bus. An Ultra DMA/33 protocol may transmit data at a rate of 33.3 MBps (megabytes per sec), which is about two times faster than compared to a DMA protocol.

The Ultra DMA may utilize a CRC (Cyclic Redundancy Checking) function to protect the data to be transmitted between a data transmitting unit (for example, host 900) and a data receiving unit (for example, solid state disk device 500). The CRC function is one technique for verifying whether an error exists in the received data. For example, the data transmitting unit (for example, host 900) may obtain a CRC code by applying a 16-bit or 32-bit polynomial to the data block and may transmit the CRC code with the data block. The data receiving unit (for example, solid state disk device 500) may generate a CRC code by applying the same polynomial as applied to the data transmitting unit to the data, and may compare the generated CRC code with the CRC code transmitted from the data transmitting unit. When two CRC codes coincide with each other, it is determined that these data are successfully received. When two CRC codes do not coincide with each other, the data receiving unit may report the CRC error code to the data transmitting unit. At this time, the data transmitting unit may retransmit the data block and the corresponding command to the data receiving unit in response to the reported CRC error code.

According to an embodiment of the inventive concept, the solid state disk device 500 may utilize the above-described CRC error code processing characteristics to process the program fail. The CRC error code originally defined in the Ultra DMA protocol may be used for processing the program fail in an embodiment of the inventive concept.

For example, in a case where the program fail occurs when the data received from the host 900 are programmed into the data storage unit 300, when the program fail occurs, the solid state disk device 500 may artificially report the CRC error code to the host 900 using the FTL 50 regardless of CRC checking results. That is, even though the CRC error does not occur, as long as the program fail occurs, the FTL 50 may report the CRC error code to the host 900. The host 900 may retransmit the program-failed data and the command (that is, program command) corresponding to the reported CRC error code to the solid state disk device 500. This configuration enables the program-failed data and the corresponding command to retransmit to the solid state disk device 500 without additional components. The data retransmitted to the solid state disk device 500 may be re-programmed into the data storage unit 300.

If only an appearance of an error is reported for processing the program fail of the flash memory without utilizing an predetermined error code (for example, CRC error code) as described above, the host 900 may expend time for finding out what errors occur in the flash memory. This is because the interface applied to a computer system or many portable data devices are not designed for an existing hard disk drive and/or because flash memory based error code does not exist for the programming/erasing characteristics of the semiconductor memory such as the flash memory. That is, the specific error code, which is defined to process the program fail that occurred in programming the flash memory, does not exist in the interface and the data transmission protocol applied the computer system or portable data device.

Hereinafter, it will describe program fail processing methods under an interface or a data transmission protocol that has no regard for the programming/erasing characteristics of the flash memory. As an example, there is a program fail processing method to which the CRC error code is not applied. As another example, there is a program fail processing method according to an embodiment of the inventive concept to which the CRC error code is applied.

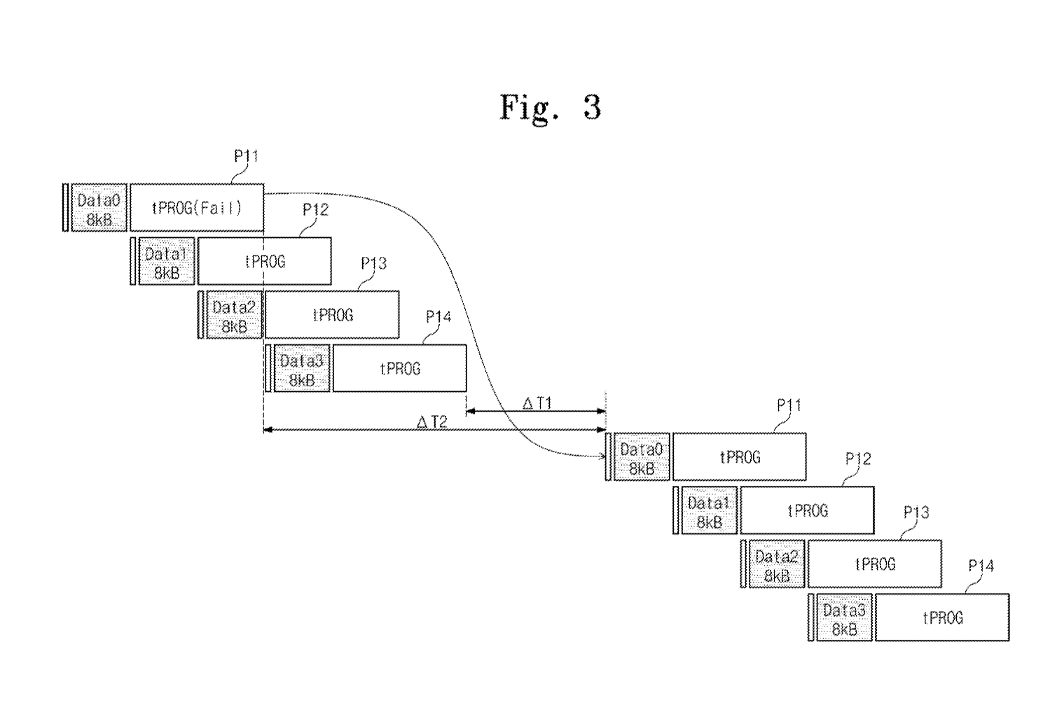

FIG. 3 is a timing diagram explaining the program fail processing method to which the CRC error code is not applied. FIG. 3 illustrates data transmission timing and program timing of the buffer memory 170 and the flash memories 310 to 330 in a case where the CRC error code is not applied to process the program fail.

Referring to FIGS. 2 and 3, the program fail occurs in the flash memories 310 to 330 during the program operation. At this time, the FTL 50 may mark a memory block programming the program-failed data as a bad block, and may move the data stored in the bad block into another memory block. The FTL 50 may manage a physical address of the bad block, and a logical address and/or a physical address of the memory block into which the data are moved from the bad block. The FTL 50 may have a bad block managing function for processing the data included in the bad block.

When the CRC error code is not applied to process the program fail, the program fail may be processed by the bad block managing function of the FTL 50. In order to write the data of the bad block on another memory block, the entire program data should be maintained in the buffer memory 170 before the program operation is normally completed. Data unit programmed into each of the flash memories 310 to 330 may have, for example, 2 kB to 8 kB of memory according to the types of flash memories 310 to 330 implemented. In a case of an interleaved program for successively programming the plurality of flash memories, the buffer memory 170 should store the entire data to be programmed to the plurality flash memories in the interleaved program.

For example, as illustrated in FIG. 3, when one page is constituted by 8 kB and the maximum 4-way interleaved programs are executed, the buffer memory 170 should have a data storage capacity capable of storing the entire program data related to 4 pages in 4 ways. In this case, the buffer memory 170 may require the data storage capacity of at least 32 kB (8 kB*4 pages ways=32 kB) to manage the bad block. In a case of applying 2-plane page program for programming data of two pages at a time into the flash memories 310 to 330, the buffer memory 170 may require the data storage capacity of at least 64 kB (2*8 kB*4 pages ways=64 kB) to manage the bad block. In addition, as the number of channels to be used in the interleaved program increases, the data storage capacity required in the buffer memory may further increase.

The bad block managing operation of the FTL 50 may be executed after the interleaved programs P11, P12, P13, and P14 are entirely completed with respect to the plurality of pagesways. Therefore, the program fail occurred at the program interval P11 of a first page data Data0 may be only recognized after a program of the fourth page data Data3 is completed. The symbol ΔT1 indicated in FIG. 3 implies a time delay from when the interleaved program including the program fail is completed to when the relevant interleaved program is restarted. Furthermore, the symbol ΔT2 indicated in FIG. 3 implies a time delay from when the program P11 of the page including the program fail is completed to when the program of the relevant page is restarted.

During a time interval ΔT1, the FTL 50 marks the memory block in which the program fail occurs as a bad block and re-executes the interleaved program including the program-failed data. The data stored in the buffer memory 170 may use 4 pages in the re-executed interleaved program. As illustrated in FIG. 3, when the CRC error code is not applied to process the program fail, the delay time ΔT2 is comparatively long from when the program of the page in which the actual program fail occurs is completed to when the program of the relevant page is restarted. In addition, the buffer memory 170 should have the data storage capacity that may entirely store the program data corresponding to 4 pages. As the data storage capacity of the buffer memory 170 increases, the size and fabricating cost of the solid state disk device 500 may increase.

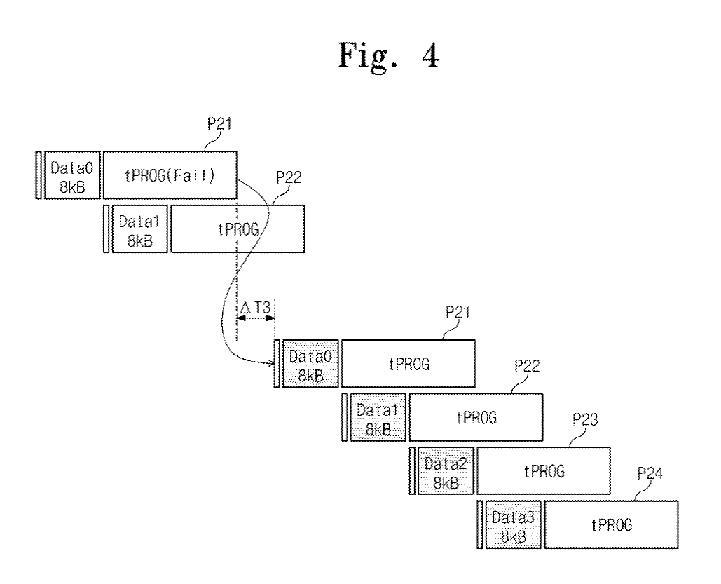

FIG. 4 is a timing diagram explaining the program fail processing method according to an embodiment of the inventive concept to which the CRC error code is applied. FIG. 4 illustrates data transmission timing and program timing of the buffer memory 170 and the flash memories 310 to 330 during the program fail processing according to an embodiment of the inventive concept.

Referring to FIGS. 2 and 4, the program fail of the flash memories 310 to 330 may randomly occur. In a case where the CRC error code is applied to process the program fail, the FTL 50 may check whether the program fail occurs in each of the flash memories whenever the program of each page data is completed. The CRC error checking operation supported by the ATA interface or Ultra-DMA protocol may be executed whenever each of the flash memories receives the program data (for example, data of at least one page unit). Therefore, when the CRC error code is used for processing the program fail, the program fail check and the reprogram operation may be executed whenever the program is completed in each page.

For example, as illustrated in FIG. 4, when one page is constituted by 8 kB and the maximum 4-way interleaved programs are executed, at the same time a program P21 is completed with respect to a first page data Data0, the program fail may be checked. That is, the program fail may be checked when the program of the first page data Data0 is completed without having to wait until interleaved program operations P21, P22, P23, and P24 corresponding to 4 pages are entirely executed.

When the program fail is detected at the program interval P21 of the first page data Data0, the FTL 50 may report the CRC error code to the host 900, and the solid sate disk device 500 may receive again the command and data corresponding to the first page data Data0 from the host 900. When the interleaved program proceeds with respect to the program-failed data, a plurality of page data to be interleaved from the program-failed data may be successively received again by the solid state disk device 500. In this case, the solid state disk device 500 may sequentially re-execute (in the order of P21, P22, P23, and P24) the interleaved program of the plurality of data Data0, Data1, Data2, and Data3 using the command and data received again from the host 900. Accordingly, there is no need to constitute or consider an additional error code and an additional program fail processing algorithm for reprogramming the program-failed data. In this case, the data Data0, Data1, Data2, and Data3 needed to re-execute the program may be received from the host 900 in response to the CRC error code. As a result, there is no need for storing the previously programmed data in the buffer memory 170 of the solid state disk device 500.

The symbol ΔT3 indicated in FIG. 4 implies a time delay from when the program fail is detected in the first page data Data0 to when the program of the first page data Data0 is re-executed. According to the program fail processing method of an embodiment of the inventive concept illustrated in FIG. 4, the delay time ΔT3 is relatively short from when the program fail is detected to when the program is re-executed as compared to the delay times of FIG. 3. Moreover, according to the program fail processing method of an embodiment of the inventive concept illustrated in FIG. 4, in the case of the interleaved program where the programs are successively executed in the plurality of flash memories, the interleaved program may be re-executed after the program fail occurs. As a result, the entire program time may be short. In addition, since an additional data storage capacity is not needed to store the previously programmed data, the size and fabricating cost of the solid state disk device 500 may be reduced.

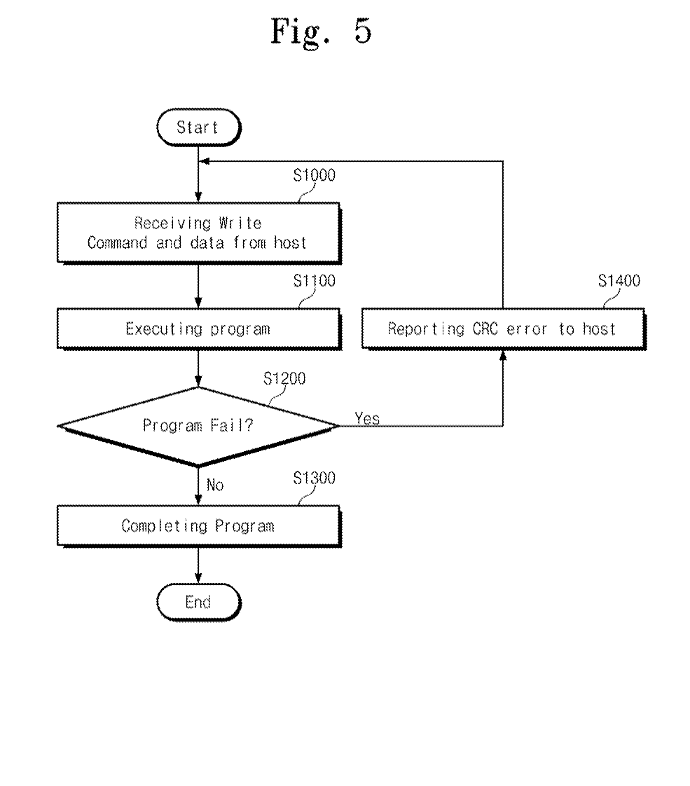

FIG. 5 is a flowchart illustrating a program fail processing method according to an embodiment of the inventive concept. Referring to FIG. 5, the solid state disk device 500 may primarily receive the program command and data from the host 900 to execute the program (S1000). At block S1000, the data received from the host 900 may comprise program data and a logical block address LBA of the program data. The LBA received from the host 900 may be converted into a physical block address PBA by the FTL 50 provided in the controller 100. The converted PBA may be provided to the corresponding flash memories 310 to 330 through the buffer memory 170 and the flash interface 180. Each of the flash memories executes the program in response to the program command and data (for example, program data and address of the program data) provided from the host 900 (S1100). At this time, the executed program may be a non-interleaved mode or an interleaved mode.

A control logic (not illustrated) is provided in the flash memories 310 to 330 to control overall operations of the flash memories 310 to 330 such as the programming, erasing, and reading operation in response to the command and data (for example, program data and address of the program data) provided from the host 900. For example, the control logic provided in the flash memories 310 to 330 may control a level and timing of a program voltage applied to a selected word line during the program operation. The program voltage Vpgm applied to the selected word line may be generated by an Incremental Step Pulse Programming (ISPP) scheme. The level of the program voltage Vpgm may gradually increase by a prescribed voltage increment AV, as program loop repeats. The number of program loops, the level of the program voltage Vpgm, and timing of the program voltage Vpgm may be changed and modified by the control of external devices (for example, controller of the solid state disk device, memory controller, and so on) or the control logic provided inside the flash memory based on program stages for each page.

The control logic (not illustrated) of the flash memory 310 to 330 may control the program operation and may internally detect the program fail. The control logic may report the program fail to the FTL 50, for example, when the program fail occurs at least a prescribed number of times or when unrecoverable errors occur. The FTL 50 may determine whether the program fail occurs in the flash memories 310 to 330 in response to the results reported by the control logic of the flash memories 310 to 330 (S1200).

At block S1200, if it is determined that the program fail does not occur, the program operation may be normally completed (S1300). However, at block S1200, if it is determined that the program fail occurs, the FTL 50 may report the CRC error code to the host 900 (S1400). In this case, even though the CRC error does not occur, as long as the program fail occurs, the FTL 50 may report the CRC error code to the host 900. After the CRC error code is reported, the process turns back to block S1000, and the host 900 retransmits the command and data corresponding to the CRC error code to the solid state disk device 500 under the CRC error processing flow originally defined in the interface or the data transmission protocol. The solid state disk device 500 may re-receive the command and data from the host at block S1000, where the data triggered detection of the program fail in the previous program operation, and the program is re-executed with respect to the re-received data at block S1100.

As described above, according to the program fail processing method of an embodiment of the inventive concept, when the program fail occurs in the flash memories 310 to 330, the CRC error code may be reported to the host 900. As a result, even when the program fail occurs, the host 900 may retransmit the corresponding command and data to the solid state disk device 500, such as when the CRC error occurs.

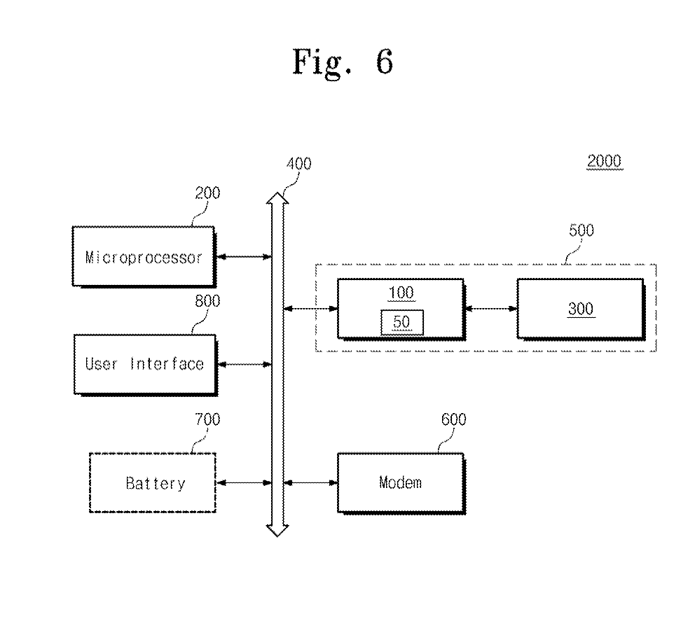

FIG. 6 is a view illustrating a computing system 2000 according to an embodiment of the inventive concept.

Referring to FIG. 6, the computing system 2000 may include a controller 100, a microprocessor 200, a data storage unit 300, a modem 600 such as a baseband chipset, and a use interface 800, which are electrically connected to a bus 400, respectively. The controller 100 and the data storage unit 300 illustrated in FIG. 6 may constitute the solid state disk device (SSD) and memory card and/or memory card system. The detailed configuration of the controller 100 and the data storage unit 300 may be the substantially same as described above. Accordingly, the same reference numerals can be denoted to the same component and the description thereof will be omitted.

N-bit data (N is an integer equal to or larger than 1), to be processed by the microprocessor 200, may be stored in the data storage unit 300 through the controller 100. The data storage unit 300 may be constituted by the nonvolatile memory that supports the plurality of channels and pagesways and, as a preferable example, by the flash memory out of the nonvolatile memory. However, the nonvolatile memory other than the flash memory may be applicable to an embodiment of the inventive concept.

The controller 100 may control the reading/writing/erasing operation of the data storage unit 300. The controller 100 may be provided with the FTL 50. The FTL 50 may manage mapping information of the data storage unit 300 so that the data storage unit 300 is used as a storage medium such as a hard disk drive or SRAM, which freely executes the reading/programming operation. The mapping results executed by the FTL 50 may be stored in the form of metadata.

Further, the FTL 50 may artificially report an error code originally defined in the interface or the data transmission protocol to the host or microprocessor 200 whenever the program fail occurs in the data storage unit 300, to substitute one of error codes originally defined in the interface or the data transmission protocol for the specific error code for the flash memories. The host and microprocessor 200 may retransmit the corresponding command and the program-failed data to the solid state disk device 500. The error code, which may be transmitted to the host and microprocessor 200 in order to retransmit the program-failed data, may be one of a plurality of error codes originally defined beforehand in the interface of the solid state disk device 500 or in the data transmission protocol of the bus.

When the computing system 2000 is a mobile device, a battery 700 may be provided additionally to supply operational voltage of the computing system 2000. Although not illustrated in the drawings, the computing system may further include an application chipset, a Camera Image Processor (CIS), a mobile DRAM, and so on. The data storage units using different types of nonvolatile memories may be implemented in laptop computers, desktop computers, and servers. In these market conditions, according to an embodiment of the inventive concept, it may be possible to improve an existing performance limit and to expand the base of the data storage unit.

According to the above-described embodiment of the inventive concept, even without an additional memory, the program operation may be executed with respect to the program-failed data. As a result, the program fail processing performance of the solid state disk device may be increased, and the size and fabricating costs may be reduced.

Preferred embodiments have been described in the specification with reference to the accompanying drawings. The terminology used therein is for the purpose of describing embodiments of the inventive concept and is not intended to be limiting of the meaning or limiting of the scope of the inventive concept described in the appended claims. Therefore, the above-disclosed subject matter is to be considered illustrative and not restrictive, and the appended claims are intended to cover all such modifications, enhancements, and other embodiments, which fall within the true spirit and scope of the inventive concept is to be determined by the broadest permissible interpretation of the following claims and their equivalents, and shall not be restricted or limited by the foregoing detailed description.

What is claimed is:

1. A solid state disk device, comprising:
at least one nonvolatile memory; and
a controller reporting an error code to a host for requesting a previously received data and a command corresponding to the data when a program fail occurs in the nonvolatile memory,
wherein the error code is one of a plurality of error codes defined in an interface supported by the controller or a data transmission protocol supported by the nonvolatile memory.

2. The solid state disk device of claim 1, wherein the error code is defined in the interface or the data transmission protocol to process errors other than the program fail.

3. The solid state disk device of claim 1, further comprising: a flash translation layer monitoring whether the program fail occurs in the nonvolatile memory and reporting the error code to the host when the program fail occurs.

4. The solid state disk device of claim 1, wherein the error code includes a CRC (Cyclic Redundancy Checking) error code.

5. The solid state disk device of claim 1, wherein the data transmission protocol includes an Ultra DMA (Direct Memory Access) protocol.

6. The solid state disk device of claim 1, wherein the interface includes an ATA (AT Attachment) interface.

7. The solid state disk device of claim 1, wherein the controller reports the error code to the host whenever the program fail is detected in the nonvolatile memory without storing the previously received data and command to additional memory.

8. A program fail processing method of a solid state disk device, the method comprising:
programming at least one nonvolatile memory in response to a program command and data received from a host;
reporting an error code to the host for requesting the data and the program command, the data and the program command being previously received, when a program fail occurs in the nonvolatile memory;
re-receiving the data and the command corresponding to the reported error code from the host; and
re-programming the data re-received from the host to the nonvolatile memory.

9. The method of claim 8, wherein the error code is one of a plurality of error codes defined in an interface or a data transmission protocol supported by the solid state disk device to process errors other than the program fail.

10. The method of claim 8, wherein the error code includes a CRC (Cyclic Redundancy Checking) error code.

11. The method of claim 8, wherein the data transmission protocol includes an Ultra DMA (Direct Memory Access) protocol.

12. The method of claim 8, wherein the interface includes an ATA (AT Attachment) interface.

13. The method of claim 8, wherein the programming and the re-programming execute an interleaved program operation that successively programs a plurality of nonvolatile memories electrically connected to a plurality of channels.

14. The method of claim 13, wherein the reporting of the error code includes reporting the error code to the host when the program fail is detected in any one of the plurality of flash memories.

15. The method of claim 8, wherein the reporting of the error code to the host is performed without storing the previously received data and program command to additional memory.

16. A computing system, comprising:
a host; and
a solid state disk device writing or reading out data by request of the host,
wherein the solid state disk device includes:
at least one nonvolatile memory; and
a controller reporting an error code to the host for requesting a previously received data and a command corresponding to the data when a program fail occurs in the nonvolatile memory, and
the error code is one of a plurality of error codes defined in an interface supported by the controller or a data transmission protocol supported by the nonvolatile memory.

17. The computing system of claim 16, wherein the controller reports the error code to the host whenever the program fail occurs in the nonvolatile memory without storing the previously received data and command to additional memory.
